(19) United States
(12) Patent Application Publication
(10) Pub. No.: US 2011/0260196 A1
(43) Pub. Date: Oct. 27, 2011

(54) LED ELEMENT AND METHOD FOR MANUFACTURING LED ELEMENT

(75) Inventors: Hiroaki OKAGAWA, Ibaraki (JP); Shin Hiraoka, Ibaraki (JP); Takahide Jouichi, Ibaraki (JP); Toshihiko Shima, Ibaraki (JP)

(73) Assignee: Mitsubishi Chemical Corporation, Tokyo (JP)

(21) Appl. No.: 13/174,105

(22) Filed: Jun. 30, 2011

Related U.S. Application Data
(63) Continuation of application No. 12/810,980, filed on Oct. 5, 2010.

(30) Foreign Application Priority Data
Dec. 28, 2007 (JP) 2007-339721

(51) Int. Cl. H01L 33/22

(52) U.S. Cl. 257/98; 257/E33.074

(57) ABSTRACT

Provided is a GaN-based LED element having a novel structure for improving output by increasing light extraction efficiency. A GaN-based LED element comprising: a semiconductor laminated structure in which an n-type GaN-based semiconductor layer is arranged on the side of a lower surface of a p-type GaN-based semiconductor layer having an upper surface and the lower surface, and a light emitting part comprising a GaN-based semiconductor is interposed between the layers; a p-side electrode formed on the upper surface of the p-type GaN-based semiconductor layer; and an n-side electrode electrically connected to the n-type GaN-based semiconductor layer, wherein the p-side electrode comprises a transparent conductive film comprising a window region serving as a window for extracting light generated in the light emitting part, and a flat section and a rough surface section formed by a roughening treatment are arranged to form a predetermined mixed pattern on the upper surface of the p-type GaN-based semiconductor layer covered with the window region of the transparent conductive film.

### TECHNICAL FIELD

The present invention relates to an LED element, and especially to an LED element using a transparent conductive film as an electrode.

Further, the invention relates to an electrode for an LED element, and especially to an electrode using a transparent conductive film.

### BACKGROUND ART

Various researches and developments have been made on a GaN-based LED element in which a light emitting device structure is constituted by using a GaN-based semiconductor. The GaN-based semiconductor is a compound semiconductor represented by the chemical formula AlₐIn_{b}Ga_{1-a-b}N (0≦a≦1, 0≦b≦1, 0≦a+b≦1), which is also called a III group nitride semiconductor, a nitride-based semiconductor or the like. The GaN-based LED element, which has become general at present, comprises a pn junction structure as a basic structure of the light emitting part, and typically has a structure in which an n-type GaN-based semiconductor and a p-type GaN-based semiconductor are formed in turn and laminated on a sapphire substrate, and electrodes are each formed on the surface of the p-type GaN-based semiconductor layer and a partially exposed surface of the n-type GaN-based semiconductor layer. This typical GaN-based LED element structure is called a horizontal electrode type structure in some cases, because when the substrate plane is liken to a horizontal plane, a current flows in the horizontal direction between the two electrodes provided on the same side of the element.

High-luminance GaN-based LED elements which emit near-ultraviolet to green light have come to be realized by adoption of a light emitting part structure such as a double heterostructure and a quantum well structure. However, in order to use the GaN-based LED elements for applications such as indoor or outdoor illumination and car headlamps, it is said that higher output power is necessary.
Patent Document 1: JP-A-2001-210867
Patent Document 2: JP-A-2007-165612
Patent Document 3: JP-A-2003-218383
Patent Document 4: International Patent Publication No. 2004/061980 Pamphlet
Patent Document 5: JP-A-2006-100518
Patent Document 6: JP-A-2006-261659
Patent Document 7: International Patent Publication No. 2005/062905 Pamphlet
Patent Document 8: JP-A-2008-235662
Patent Document 9: U.S. Patent Application Publication No. 2004/206969

### DISCLOSURE OF THE INVENTION

### Problems that the Invention is to Solve

It is known that the use of a TCO (transparent conductive oxide) film such as an ITO (indium tin oxide) film as an electrode is effective as a means for obtaining a high power GaN-based LED element (patent document 1). Recently, there is known a GaN-based LED element in which the approximately whole surface of the p-type GaN-based semiconductor layer serving as a light extracting surface is subjected to a roughening treatment to form an uneven surface, and an electrode comprising a TCO film is formed on the uneven surface, for obtaining higher output power (patent document 2, patent document 9).

However, there is a problem that a roughening treatment of the surface of a p-type GaN-based semiconductor causes an increase in contact resistance of an electrode formed on the surface, which further causes an increase in Vf (forward voltage) of an LED element. In the invention disclosed in patent document 9, it seems that this problem is not particularly considered. On the other hand, in the invention disclosed in patent document 2, a structure for decreasing the contact resistance is provided at an interface between the surface of the p-type GaN-based semiconductor subjected to the roughening treatment and the TCO film, as a means for solving this problem.

In contrast, the present inventors have found that while the roughening treatment is performed on the surface of the p-type GaN-based semiconductor layer, an increase in Vf of the LED element associated therewith can be prevented by a means completely different from the invention disclosed in patent document 2, thus reaching the invention.

A main object which the invention intends to attain is to provide a GaN-based LED element which can be suitably used for applications requiring high output power, including illumination applications, and more specifically to further improve a GaN-based LED element using a TCO film as an electrode to increase output power.

### Means for Solving the Problems

The invention provides the following invention relating to an LED element in a first aspect thereof.

(a-1) An LED element comprising: a semiconductor laminated structure in which a second semiconductor layer different from a first semiconductor layer in conductive type is arranged on the side of a lower surface of the first semiconductor layer having an upper surface and the lower surface, and a light emitting part is interposed between the layers; a first electrode formed on the upper surface of the first semiconductor layer; and a second electrode electrically connected to the second semiconductor layer, wherein the first electrode comprises a transparent conductive film comprising a window region serving as a window for extracting light generated in the light emitting part, and a flat section and a rough surface section formed by a roughening treatment are arranged to form a predetermined mixed pattern on the upper surface of the first semiconductor layer covered with the window region of the transparent conductive film.

In the LED element described in the above (a-1), the light generated in the light emitting part in the semiconductor laminated structure can be efficiently extracted to the outside of the element through the transparent conductive film. This is because the light, which cannot escape outside the semiconductor laminated structure due to total reflection or Fresnel reflection when the rough surface section is not provided, can escape outside the semiconductor laminated structure through the rough surface section provided on the surface of the first semiconductor layer.

In the LED element described in the above (a-1), not only the rough surface section is provided on the surface of the first semiconductor layer covered with the transparent conductive film, but also the flat section is provided in a mixed state with the rough surface section, thereby keeping a good electrical connection between the first semiconductor layer and the transparent conductive film. A roughening treatment of a semiconductor surface on which an electrode is formed frequently causes an increase in contact resistance between the semiconductor and the electrode. The cause thereof can be a decrease in carrier concentration of the semiconductor due to damage which the semiconductor suffers by the roughening treatment, and further can be a deterioration of a contact state at the junction between the semiconductor and the electrode.

In the LED element described in the above (a-1), the transparent conductive film is formed in such a manner that a portion which covers the flat section of the upper surface of the first semiconductor layer and a portion which covers the rough surface section of the upper surface of the first semiconductor layer are continuous. Accordingly, of the light which enters from the first semiconductor layer side to the inside of the transparent conductive film on the flat section, a component which is not emitted to the outside of the element and propagates in the inside of the transparent conductive film is scattered by the rough surface section of the first semiconductor layer surface, thereby being able to extract it to the outside of the element. Further, by forming the transparent conductive film in such a manner, a current to be supplied to the first semiconductor layer can be sufficiently diffused in a layer direction (a direction perpendicular to a layer thickness direction) by the transparent conductive film.

The invention provides the following invention relating to a GaN-based LED element in a second aspect thereof.

(b-1) A GaN-based LED element comprising: a semiconductor laminated structure in which an n-type GaN-based semiconductor layer is arranged on the side of a lower surface of a p-type GaN-based semiconductor layer having an upper surface and the lower surface, and a light emitting part comprising a GaN-based semiconductor is interposed between the layers; a p-side electrode formed on the upper surface of the p-type GaN-based semiconductor layer; and an n-side electrode electrically connected to the n-type GaN-based semiconductor layer, wherein the p-side electrode comprises a transparent conductive film comprising a window region serving as a window for extracting light generated in the light emitting part, and a flat section and a rough surface section formed by a roughening treatment are arranged so as to form a predetermined mixed pattern on the upper surface of the p-type GaN-based semiconductor layer covered with the window region of the transparent conductive film.

(b-2) The LED element described in the above (b-1), wherein the above-mentioned predetermined mixed pattern comprises one or more mixed patterns selected from (i) a mixed pattern in which the flat section(s) and the rough surface section(s) showing parallel stripes are alternately arranged, (ii) a mixed pattern in which either the flat section or the rough surface section show a net-like pattern and (iii) a mixed pattern in which the flat sections are each in contact with the adjacent flat sections at points, and the rough surface sections are each in contact with the adjacent rough surface sections at points.

(b-3) The LED element described in the above (b-1) or (b-2), wherein the predetermined mixed pattern comprises a periodic pattern.

(b-4) The LED element described in any one of the above (b-1) to (b-3), wherein an area proportion of the flat section in the predetermined mixed pattern is from 20% to 90%.

(b-5) The LED element described in any one of the above (b-1) to (b-4), wherein the p-side electrode comprises a metal p-side pad electrode connected to the transparent conductive film; and, a portion of the upper surface of the p-type GaN-based semiconductor layer contained in an orthogonal projection of the p-side pad electrode when considering the upper surface as a projection plane is not subjected to the roughening treatment, and the p-type GaN-based semiconductor layer has the same surface roughness in the portion and in the above-mentioned flat section.

(b-6) The LED element described in the above (b-5), wherein the portion of the upper surface of the p-type GaN-based semiconductor layer which is contained in the orthogonal projection of the p-side pad electrode and not subjected to the roughening treatment has an rms (root mean square) surface roughness of less than 1 nm within an area of 5×5 μm².

(b-7) The LED element described in the above (b-5) or (b-6), wherein current supply from the p-side electrode to the p-side GaN-based semiconductor layer through a region in the upper surface of the p-type GaN-based semiconductor layer, the region being contained in a orthogonal projection of the p-side pad electrode when considering the upper surface as a projection plane, is blocked.

(b-8) The LED element described in any one of the above (b-1) to (b-7), wherein the p-side electrode comprises a metal p-side pad electrode formed on the transparent conductive film; and the transparent conductive film comprises a portion lower in surface smoothness than a portion covered with the p-side pad electrode, on the above-mentioned flat section.

(b-9) The LED element described in any one of the above (b-1) to (b-8), wherein the n-type GaN-based semiconductor layer comprises a portion protruding outside the semiconductor laminated structure, and the n-side electrode is formed on the protruding portion, thereby forming a horizontal electrode type device structure; the p-side electrode comprises a metal p-side pad electrode formed on the transparent conductive film; the n-side electrode comprises a metal n-side pad electrode; and an area proportion of the rough surface section in the upper surface of the p-type GaN-based semiconductor layer covered with the window region of the transparent conductive film is higher in the inside of a region sandwiched between the p-side pad electrode and the n-side pad electrode, when the LED element is plan-viewed, than in the outside of the region.

(b-10) The LED element described in any one of the above (b-1) to (b-9), wherein the transparent conductive film comprises a TCO film.

(b-11) The LED element described in the above (b-10), wherein the above-mentioned TCO film is formed of an oxide containing at least one element selected from Zn, In, Sn and Ti.

(b-12) The LED element described in any one of the above (b-1) to (b-11), wherein the roughening treatment is a roughening treatment comprising a dry etching treatment of the surface of the p-type GaN-based semiconductor layer.

The invention provides the following invention relating to a GaN-based LED element in a third aspect thereof.

(c-1) A GaN-based LED element comprising: a semiconductor laminated structure in which an n-type GaN-based semiconductor layer is arranged on the side of a lower surface of a p-type GaN-based semiconductor layer having an upper surface and the lower surface, and a light emitting part comprising a GaN-based semiconductor is interposed between the layers; a p-side electrode formed on the upper surface of the p-type GaN-based semiconductor layer; and an n-side electrode electrically connected to the n-type GaN-based semiconductor layer, the n-type GaN-based semiconductor layer comprising a portion protruding outside the semiconductor laminated structure, and the n-side electrode being formed on the protruding portion, thereby forming a horizontal electrode type device structure, wherein the p-side electrode comprises a transparent conductive film comprising a window region serving as a window for extracting light generated in the light emitting part, a flat section and a rough surface section formed by a roughening treatment are arranged on the upper surface of the p-type GaN-based semiconductor layer covered with the window region of the transparent conductive film, the p-side electrode comprises a metal p-side pad electrode formed on the transparent conductive film, the n-side electrode comprises a metal n-side pad electrode, and the area proportion of the rough surface section in the upper surface of the p-type GaN-based semiconductor layer covered with the window region of the transparent conductive film is higher in the inside of a region sandwiched between the p-side pad electrode and the n-side pad electrode, when the LED element is plan-viewed, than in the outside of the region.

The invention provides the following invention relating to a method for producing a GaN-based LED element in a fourth aspect thereof.

(d-1) A method for producing a GaN-based LED element, the method comprising: (A) a step of preparing a semiconductor structure comprising on a substrate a semiconductor laminated structure in which an n-type GaN-based semiconductor layer is arranged on the side of a lower surface of a p-type GaN-based semiconductor layer having an upper surface and the lower surface, and a light emitting part comprising a GaN-based semiconductor is interposed between the layers; (B) a step of forming a first transparent conductive film into a predetermined pattern on the p-type GaN-based semiconductor layer in such a manner that the upper surface of the p-type GaN-based semiconductor layer is partially exposed; (C) a step of providing a flat section and a rough surface section on the upper surface of the p-type GaN-based semiconductor layer by subjecting at least a part of the exposed upper surface of the p-type GaN-based semiconductor layer to a roughening treatment after the step of (B); and (D) a step of forming a second transparent conductive film which constitutes an electrode for the p-type GaN-based semiconductor layer together with the first transparent conductive film in such a manner that at least a part of the rough surface section and at least a part of the first transparent conductive film are covered with the second transparent conductive film.

(d-2) The production method described in the above (d-1), wherein the roughening treatment in the step (C) is a roughening treatment comprising dry etching.

(d-3) The production method described in the above (d-2), wherein the first transparent conductive film is a polycrystalline film; patterning of the first transparent conductive film is performed by a subtractive method in such a manner that a residue of the first transparent conductive film remains on the exposed upper surface of the p-type GaN-based semiconductor layer, in the step (B); and the roughening treatment in the step (C) is a roughening treatment comprising dry etching using the residue of the first transparent conductive film as a mask.

According to the production methods described in the above (d-1) to (d-3), the first transparent conductive film is formed before the rough surface section is formed on the upper surface of the p-type GaN-based semiconductor layer, so that fluctuation in voltage characteristics of the LED element is suppressed. This is because the less is the number of processes before the formation of the first transparent conductive film, the lower is the degree of damage and contamination suffered by the surface of the p-side GaN-based semiconductor layer, which become a cause of fluctuation in contact resistance between the first transparent conductive film and the p-side GaN-based semiconductor layer.

The production methods described in the above (d-1) to (d-3) can be suitably used in the production of the GaN-based LED elements described in the above (b-1) to (b-12) and (c-1).

The invention provides the following invention relating to an LED element in a fifth aspect thereof.

(e-1) An LED element comprising: a semiconductor laminated structure in which a second semiconductor layer different from a first semiconductor layer in conductive type is arranged on the side of a lower surface of the first semiconductor layer having an upper surface and the lower surface, and a light emitting part is interposed between the layers; a first electrode formed on the upper surface of the first semiconductor layer; and a second electrode electrically connected to the second semiconductor layer, wherein the second semiconductor layer comprises a portion protruding outside the semiconductor laminated structure, and the second electrode is formed on the protruding portion, thereby forming a horizontal electrode type device structure, wherein the second electrode comprises a transparent conductive film comprising a window region serving as a window for extracting light generated in the light emitting part, and a flat section and a rough surface section formed by a roughening treatment are arranged to form a predetermined mixed pattern on a surface of the second semiconductor layer covered with the window region of the transparent conductive film.

(e-2) The LED element described in the above (e-1), which is a GaN-based LED element.

(e-3) The LED element described in the above (e-2), wherein the first semiconductor layer is a p-type GaN-based semiconductor layer, and the second semiconductor layer is an n-type GaN-based semiconductor layer.

The invention provides the following invention relating to an electrode for an LED element in a sixth aspect thereof.

(f-1) An electrode for an LED element, the electrode comprising a transparent conductive film comprising a window region serving as a window for extracting light emitted by the LED element and a metal pad electrode formed on a part of the transparent conductive film, wherein the transparent conductive film comprises a high smoothness film having relatively high surface smoothness and a low smoothness film having relatively low surface smoothness, the whole or the greater part of the pad electrode is formed on the high smoothness film, and at least a part of the low smoothness film is exposed in the window region.

(f-2) The electrode for an LED element described in the above (f-1), which comprises a portion where the high smoothness film is laminated on the low smoothness film.

(f-3) The electrode for an LED element described in the above (f-1), which comprises a portion where the low smoothness film is laminated on the high smoothness film.

(f-4) The electrode for an LED element described in any one of the above (f-1) to (f-3), which comprises an insulating film formed in contact with a back surface of the transparent conductive film in a region directly under the pad electrode.

(f-5) The electrode for an LED element described in any one of the above (f-1) to (f-4), which is an electrode for a GaN-based LED element.

### Advantages of the Invention

The GaN-based LED element in which the invention is embodied becomes one excellent in light emitting output, so that it can be suitably used for applications requiring high output power, including illumination applications.

### BRIEF DESCRIPTION OF THE DRAWINGS

FIG. 1 is a schematic cross-sectional view of a GaN-based LED element according to an embodiment of the invention.

FIG. 2 is a schematic cross-sectional view of a GaN-based LED element according to an embodiment of the invention.

FIG. 3 is a schematic cross-sectional view of a GaN-based LED element according to an embodiment of the invention.

FIG. 4 is a schematic cross-sectional view of a GaN-based LED element according to an embodiment of the invention.

FIG. 5 is a view for illustrating a production process of the GaN-based LED element shown in FIG. 4.

FIG. 6 is a view for illustrating a production process of the GaN-based LED element shown in FIG. 4.

FIG. 7 is a view for illustrating a production process of the GaN-based LED element shown in FIG. 4.

FIG. 8 is a view for illustrating a production process of the GaN-based LED element shown in FIG. 4.

FIG. 9 is schematic views of a GaN-based LED element according to an embodiment of the invention, wherein FIG. 9(a) is a plan view of the element viewed from the side of an electrode-arranged surface, and FIG. 9(b) is a cross-sectional view taken along line X-X in FIG. 9(a).

FIG. 10 is views exemplifying net-like patterns. In each of FIGS. 10(a) to 10(f), a portion marked out with dots shows a net-like pattern.

FIG. 11 is views exemplifying net-like patterns. In each of FIGS. 11(a) and 11(b), a portion marked out with dots shows a net-like pattern.

FIG. 12 is views exemplifying mixed patterns in which flat sections are each in contact with adjacent flat sections at points, and rough surface sections are each in contact with adjacent rough surface sections at points. In each of FIGS. 12(a) to 12(g), portions marked out with dots may be either the flat sections or the rough surface sections.

### DESCRIPTION OF REFERENCE NUMERALS AND SIGNS

10, 20, 30, 40, 50: GaN-based LED element

11, 21, 31, 41, 51: Substrate

12, 22, 32, 42, 52: GaN-based semiconductor film

121, 221, 321, 421, 521: n-Type layer

122, 222, 322, 422, 522: p-Type layer

13, 23, 33, 43, 53: n-Side pad electrode

14, 24, 34, 44, 54: TCO film

15, 25, 35, 45, 55: p-Side pad electrode

60: Constriction

### BEST MODE FOR CARRYING OUT THE INVENTION

The invention will be described below in more detail with reference to specific embodiments. Incidentally, it is previously stated that the respective embodiments are not carried out for all of various aspects of the invention.

### Embodiment 1

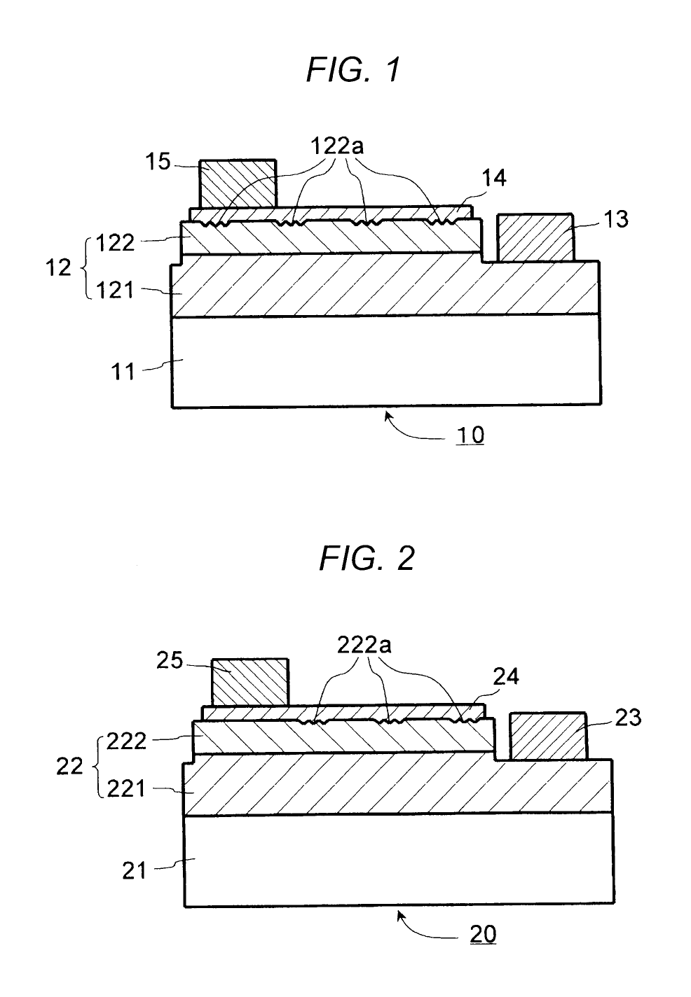

FIG. 1 is a schematic cross-sectional view showing a structure of a GaN-based LED element according to Embodiment 1 of the invention. The GaN-based LED element 10 comprises a GaN-based semiconductor film 12 formed on a substrate 11 via a buffer layer (not shown). The GaN-based semiconductor film 12 comprises an n-type layer 121 composed of an n-type conductive GaN-based semiconductor and a p-type layer 122 composed of a p-type conductive GaN-based semiconductor in this order from the substrate side. A metal n-side pad electrode 13 also serving as an ohmic electrode is formed on a surface of the n-type layer 121 exposed in a portion where the p-type layer 122 is partially removed. A TCO film 14 is formed as an electrode on the surface of the p-type layer 122, and a metal p-side pad electrode 15 is formed on a part of the TCO film 14.

Rough surface sections 122a subjected to a roughening treatment are partially formed on the surface of the p-type layer 122. Fine unevenness having a level difference of about 10 to 100 nm is formed in the rough surface sections 122a. The surface not subjected to the roughening treatment is a flat surface having an rms roughness of less than 1 nm.

When a forward current is applied to the GaN-based LED element 10 through the n-side pad electrode 13 and the p-side pad electrode 15, light is emitted at a pn junction formed in the GaN-based semiconductor film 12. The refractive index of the p-type layer 122 composed of a GaN-based semiconductor is higher than that of the TCO film 14, so that reflection of light (total reflection, Fresnel reflection) occurs at an interface between the p-type layer 122 and the TCO film 14. However, this reflection is weakened by providing the rough surface sections 122a, and the light is efficiently extracted to the outside of the LED element 10 through the TCO film 14. Incidentally, when the TCO film is a polycrystalline film such as an ITO film, fine unevenness reflecting the shape of crystal grain boundaries is formed in the surface of the TCO film, so that the reflection at the TCO film surface becomes relatively weak.

The roughening treatment of the surface of the p-type layer 122 is performed by dry etching (for example, plasma etching or reactive ion etching). Here, it is known that an electrode showing good ohmic properties (an electrode sufficiently low in contact resistance with a p-type GaN-based semiconductor) cannot be formed on a dry-etched surface of a p-type GaN-based semiconductor. The reason for this is that autocompensation of carriers occur because nitrogen vacancies formed at high concentration by dry etching has donor properties, resulting in a decrease in hole carrier concentration in the semiconductor. From such circumstances, in the GaN-based LED element 10, only a part of the surface of the p-type layer 122 is subjected to the roughening treatment in such a manner that the formation of an ohmic electrode becomes possible while improving light extraction efficiency. As a result of such a roughening treatment, the current supplied from the TCO film 14 to the p-type layer 122 flows mainly through a contact portion of the flat section of the p-type layer 122 and the TCO film 14.

### Embodiment 2

FIG. 2 is a schematic cross-sectional view showing a structure of a GaN-based LED element according to Embodiment 2 of the invention. The GaN-based LED element 20 comprises a GaN-based semiconductor film 22 formed on a substrate 21 via a buffer layer (not shown). The GaN-based semiconductor film 22 comprises an n-type layer 221 composed of an n-type conductive GaN-based semiconductor and a p-type layer 222 composed of a p-type conductive GaN-based semiconductor in this order from the substrate side. A metal n-side pad electrode 23 also serving as an ohmic electrode is formed on a surface of the n-type layer 221 exposed in a portion where the p-type layer 222 is partially removed. A TCO film 24 is formed as an electrode on a surface of the p-type layer 222, and a metal p-side pad electrode 25 is formed on a part of the TCO film 24.

The GaN-based LED element 20 according to Embodiment 2 is characterized in that the p-type layer 222 comprises rough surface sections 222a only in regions other than a region directly under the p-side pad electrode 25, and that the p-type layer surface directly under the p-side pad electrode 25 is not roughened and is left flat.

Because the reflectance of a metal surface is not so high at all, the p-side pad electrode acts as a light absorber. Further, when trying to extract light generated in the GaN-based semiconductor film from an element surface on the side where the p-side pad electrode is arranged, the p-side pad electrode serves as a light shield. In order to suppress a decrease in light extraction efficiency due to such unfavorable action of the p-side pad electrode, the GaN-based LED element 20 is constituted in such a manner that the p-type layer 222 comprises no rough surface section 222a in the region directly under the p-side pad electrode 25. This is because if the rough surface section 222a is present in the region, the amount of light incident to the back surface (surface in contact with the TCO film 24) of the p-side pad electrode 25 increases through the weakening in the reflection at the interface between the p-type layer 222 and the TCO film 24.

The above-described effect obtained by providing no rough surface section of the p-type layer directly under the p-side pad electrode becomes particularly significant when the TCO film is a polycrystalline film. As described above, fine unevenness reflecting the shape of crystal grain boundaries is formed on the surface of a polycrystalline TCO film. When the p-side pad electrode is formed on such a surface of the TCO film, the fine unevenness of the TCO film is transferred to the back surface of the p-side pad electrode, resulting in a decrease in the reflectance of the back surface. That is to say, the action of the p-side pad electrode as a light absorber is enhanced. For this reason, the reduction of the amount of light incident to the back surface of the p-side pad electrode becomes particularly effective for preventing a decrease in the light extraction efficiency.

### Embodiment 3

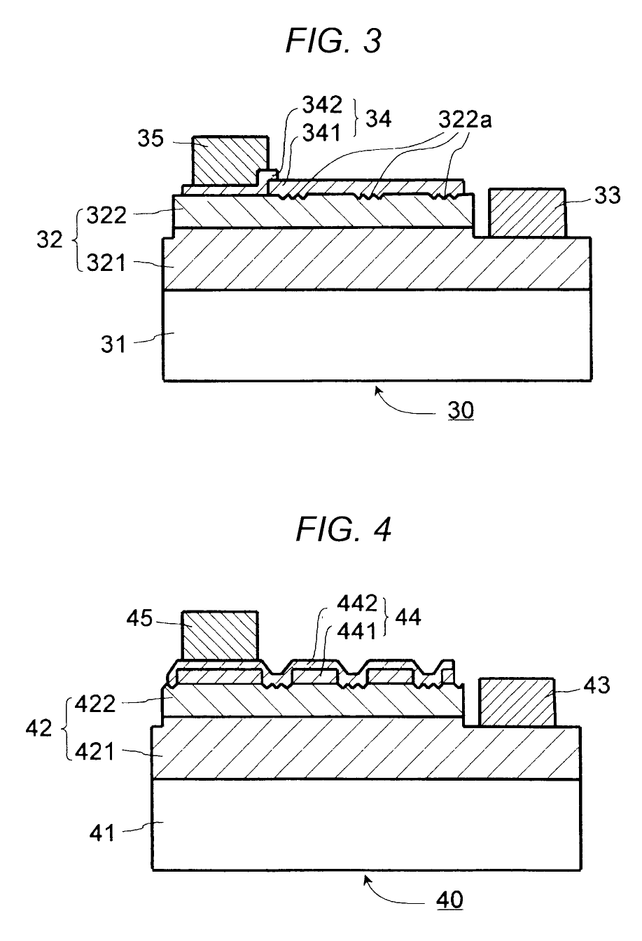

FIG. 3 is a schematic cross-sectional view showing a structure of a GaN-based LED element according to Embodiment 3 of the invention. The GaN-based LED element 30 comprises a GaN-based semiconductor film 32 formed on a substrate 31 via a buffer layer (not shown). The GaN-based semiconductor film 32 comprises an n-type layer 321 composed of an n-type conductive GaN-based semiconductor and a p-type layer 322 composed of a p-type conductive GaN-based semiconductor in this order from the substrate side. A metal n-side pad electrode 33 also serving as an ohmic electrode is formed on a surface of the n-type layer 321 exposed in a portion where the p-type layer 322 is partially removed. A TCO film 34 is formed as an electrode on a surface of the p-type layer 322, and the TCO film 34 is constituted of a first TCO film 341 and a second TCO film 342. In addition, a metal p-side pad electrode 35 is formed on the second TCO film 342.

In the GaN-based LED element 30, these two TCO films are formed in such a manner that the contact resistance between the first TCO film 341 and the p-type layer 322 is lower than the contact resistance between the second TCO film 342 and the p-type layer 322. The contact resistances of the two TCO films with the p-type GaN-based semiconductor can be made different by the following methods.

In a method, the two TCO films are formed by using different film forming methods. For example, the first TCO film 341 is formed by a vacuum vapor deposition method, a laser ablation method or a sol-gel method, and the second TCO film 342 is formed by a sputtering method. With respect to TCOs such as ITO (indium tin oxide), tin oxide, indium oxide and zinc oxide, it is known that a film formed by a vacuum vapor deposition method, a laser ablation method or a sol-gel method shows lower contact resistance with a p-type GaN-based semiconductor than one formed by a sputtering method (patent document 1: JP-A-2001-210867).

In a method, the first TCO film 341 is formed to be a film with higher carrier concentration than the second TCO film 342. It is said that a tunnel junction is formed between TCO, which is an n-type conductive material, and a p-type GaN-based semiconductor, and the higher is the carrier concentration of TCO film, the lower is its contact resistance with a p-type GaN based semiconductor. A method for controlling the carrier concentration of TCO film is well known. In the case of ITO (indium tin oxide), the carrier concentration can be controlled by Sn (tin) concentration or oxygen concentration. Accordingly, in the case of film formation by a vacuum vapor deposition method, ITO films with different carrier concentrations can be formed by varying the composition of vapor deposition materials and the oxygen partial pressure at the time of vapor deposition. Further, with respect to ITO, it is also known that the carrier concentration of a film formed by a vacuum vapor deposition method is higher than that of a film formed by a spray pyrolysis method. In addition, it is known that films with different carrier concentrations can be formed by controlling the amount of an impurity such as Sb (antimony), F (fluorine) and P (phosphorous) in the case of tin oxide, and by controlling the amount of an impurity such as Al (aluminum) and Ga (gallium) in the case of zinc oxide.

A method utilizing a hydrogen passivation phenomenon is also usable. In this method, the first TCO film 341 is formed into a predetermined shape on the surface of the p-type layer 322, and then, a hydrogen gas, an ammonia gas or the like is brought into contact with the surface of the p-type layer 322, which is not covered with the first TCO film 341 and exposed, at 400° C. or more, thereby insulating the surface by hydrogen passivation of a p-type impurity. Thereafter, the second TCO film 342 is formed on the insulated surface of the p-type layer 322.

In the GaN-based LED element 30, the current supplied from the p-side pad electrode 35 flows from the second TCO film 342 to the p-type layer 322 through the first TCO film 341 by forming p-side pad electrode 35 on the second TCO film which is a TCO film having higher contact resistance with the p-type layer 322. In other words, in the GaN-based LED element 30, the supply of the current from the TCO film 34 to the p-type layer 322 directly under the p-side pad electrode 35 is blocked. Accordingly, light emission at the pn junction in the GaN-based semiconductor film 32 is suppressed directly under the p-side pad electrode 35. As a result, the amount of light absorbed and/or shielded by the p-side pad electrode 35 decreases, so that the light extraction efficiency is improved.

In a region directly under the pad electrode, when the current supply to the semiconductor is not blocked unlike an example of this Embodiment 3, the density of the current flowing in the electrode-semiconductor interface or in the semiconductor becomes high and the progress of thermal degradation of the materials by Joule heat is thereby accelerated. As a result, the life of the whole element depends on the life of parts contained in the region in some cases. From this, it is also preferred in terms of improving the element life to block the current supply to the semiconductor directly under the pad electrode.

### Modified Example of Embodiment 3

The GaN-based LED element 30 according to the above-mentioned embodiment 3 has a contact interface between the TCO film 342 and the p-type layer 322 directly under the p-side pad electrode 35. In a modified example, instead of this, an insulating film is interposed between the TCO film and the p-type layer, thereby blocking the current supply from the TCO film to the p-type layer directly under the p-side pad electrode. The preferred insulating film is a transparent thin film made of an inorganic material having low light absorptivity. Here, suitable examples of the inorganic materials are metal oxides, metal nitrides and metal oxynitrides such as silicon oxide, silicon nitride, silicon oxynitride, aluminum oxide, zirconium oxide and niobium oxide. When a low refractive film having a lower refractive index than the p-type layer is formed to a film thickness of 0.1 μm or more as the transparent thin film, the amount of light incident to the back surface of the p-side pad electrode can be decreased. Preferred materials for the low refractive film are materials having a difference from the p-type layer in refractive index of 0.5 or more, such as silicon oxide and aluminum oxide.

### Embodiment 4

FIG. 4 is a schematic cross-sectional view showing a structure of a GaN-based LED element according to Embodiment 4 of the invention. In the GaN-based LED element 40 according to Embodiment 4, a TCO film 44 formed on a p-type layer 422 is constituted of a first TCO film 441 and a second TCO film 442, and for the contact resistance with the p-type layer 422, the first TCO film 441 is lower than the second TCO film 442, as is the case with the GaN-based LED element 30 according to Embodiment 3.

The GaN-based LED element 40 is characterized in that the first TCO film 441 is patterned so as to partially cover the surface of the p-type layer 422, that in the surface of the p-type layer 422, a portion not covered with the first TCO film 441 is roughened, and that the second TCO film 442 is formed so as to be in contact with both an exposed surface of the p-type layer 422 and the surface of the first TCO film 441. In the GaN-based LED element 40, the surface of the second TCO film 442 forms a gentle uneven surface, so that the occurrence of multiple reflection with the second TCO film 442 serving as one reflective surface is suppressed.

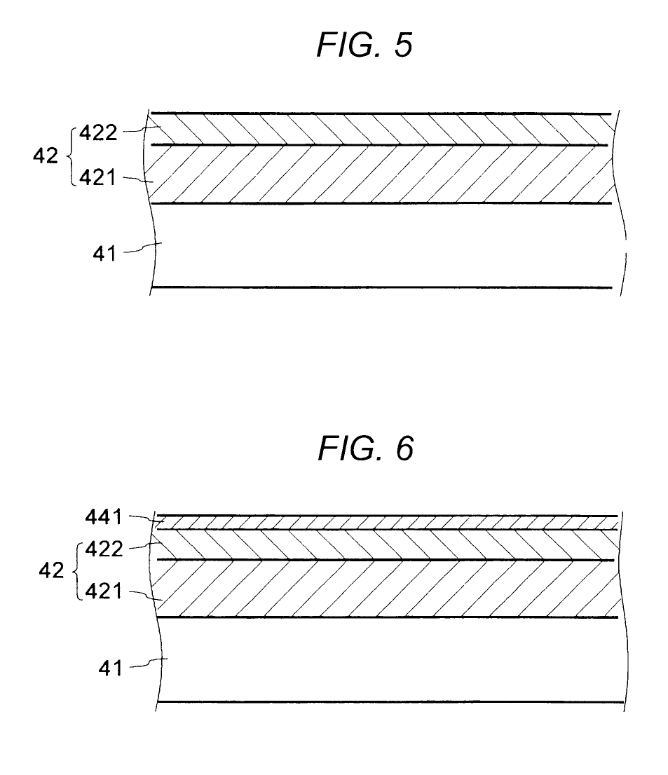

In order to produce the GaN-based LED element 40, first, the n-type layer 421 and the p-type layer 422 are grown on a substrate 41 by a MOVPE method to be laminated, as shown in FIG. 5. After the lamination, an annealing treatment is performed as needed to activate a p-type impurity added to the p-type layer 422.

Next, as shown in FIG. 6, the first TCO film 441 is formed so as to cover the whole surface of the p-type layer 422 which is an as-grown surface. The surface of the p-type layer 422 is desirably acid-washed before the formation of the TCO film. The first TCO film 441 is preferably a polycrystalline film.

Then, a photoresist film is formed on the first TCO film 441, and this photoresist film is patterned into a predetermined shape by using photolithography technique.

Thereafter, of the first TCO film 441, a portion not covered with the photoresist film and exposed is removed by dry etching, thereby patterning the first TCO film 441. After the removal of the first TCO film 441, the etching treatment is continued as it is, thereby roughening the surface of the p-type layer 422 exposed by removing the first TCO film. In this step, in the case where the first TCO film is a polycrystalline film, the etching rate becomes uneven (a grain boundary portion is etched faster than a crystal portion) in the film plane, so that a state occurs where the crystal portion of the TCO film having a low etching rate partially remains on the exposed surface of the p-type layer 422. When the etching is further continued, because the TCO crystals act as an etching mask, the roughened surface of the p-type layer 422 becomes an uneven surface having a large level difference between concave portions and convex portions.

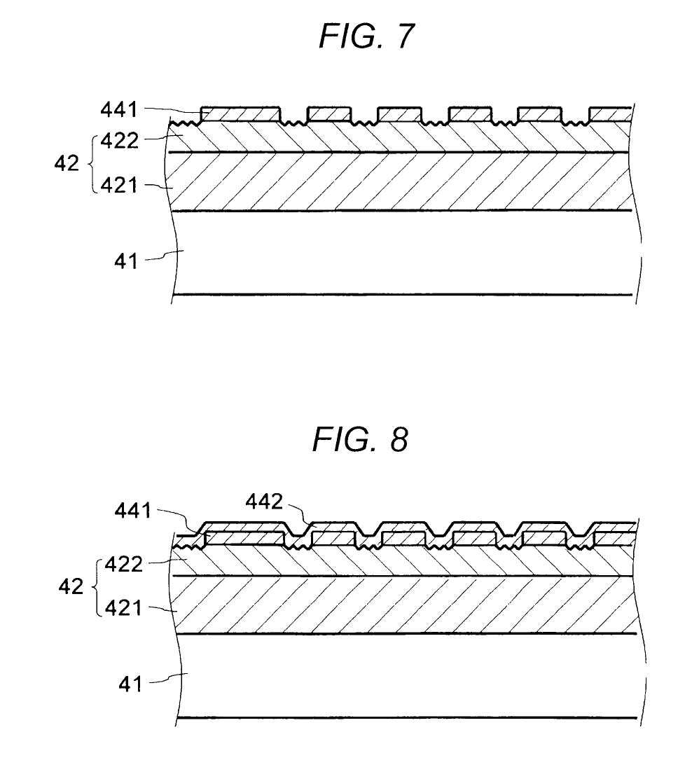

When the photoresist film is removed after the dry etching treatment, a state is obtained where the surface of the p-type layer 422 is partially covered with the first TCO film 441 and the surface of the p-type layer 422 not covered with the first TCO film 441 is roughened, as shown in FIG. 7.

Thereafter, as shown in FIG. 8, the second TCO film 442 is formed so as to cover both the exposed surface of the p-type layer 422 and the surface of the first TCO film 441.

After the second TCO film 442 is formed, patterning of the TCO film 42 (composite film of the first TCO film 441 and the second TCO film 442), partial exposure of the n-type layer 421 by dry etching, formation of an n-side pad electrode 43 and a p-side pad electrode 45, device separation, formation of an insulating protective film and dicing are in turn performed by using methods usually used in this field.

In the GaN-based LED element 40, there is no particular limitation on the pattern of the first TCO film 441, and there can be used various patterns such as net-like, comb-like and branch-like patterns, a pattern in which a plurality of stripes are arranged parallel to one another and a pattern in which a plurality of dots are dispersed. The pattern may be one having high regularity or one having strong randomness. For example, in the case of the pattern in which dots are dispersed, it may be a pattern in which the respective dots have variations in shape or size, or a pattern in which there is no clear periodicity in arrangement of the dots.

When the first TCO film 441 is formed into a pattern constituted of a plurality of island-like isolated portions, the second TCO film 442 functions to electrically connect the respective isolated portions of the first TCO film 441.

The area proportion of rough surface sections in a portion of the surface of the p-type layer 422 where the layer is in contact with the TCO film 44 can be controlled by patterning of the first TCO film 441. In the rough surface sections, current injection into the p-type layer 422 does not substantially occur. Accordingly, for example, in a part where the current concentrates from an element structural reason (a part where the density of the current flowing across a pn junction plane is high), the current supplied to the p-type layer 422 is decreased by setting the area proportion of this rough surface section large, thereby being able to equalize the intensity of the light generated at the pn junction in the pn junction plane.

### Modified Example of Embodiment 4

In the production method of the GaN-based LED element according to the above-mentioned Embodiment 4, when the first TCO film 441 is patterned, an unnecessary portion thereof is removed by dry etching. In a modified example, removal of the unnecessary portion of the first TCO film is performed by wet etching, instead of dry etching. When the first TCO film is a polycrystalline film, a grain boundary portion is etched faster than the crystal portion also in the case of wet etching. Accordingly, a fine residue of the crystal portion can be allowed to remain on the exposed surface of the p-type layer, and when the exposed surface of the p-type layer is subjected to the roughening treatment in a post process, this residue can be used as an etching mask.

### Embodiment 5

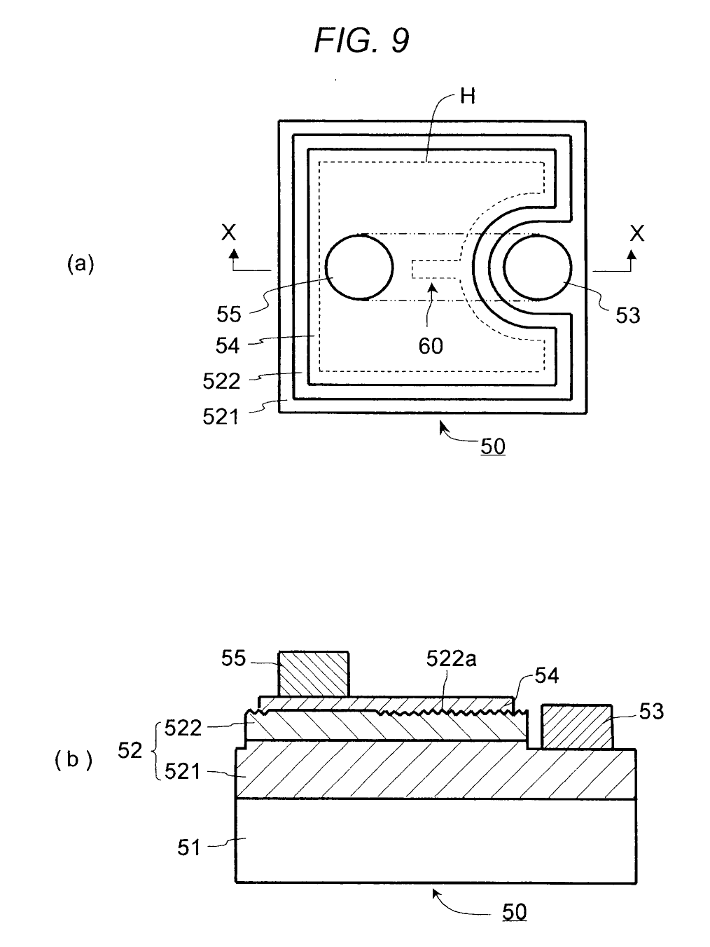

FIG. 9 is schematic views of a GaN-based LED element according to Embodiment 5 of the invention, wherein FIG. 9(a) is a plan view of the element viewed from the side of an electrode-arranged surface, and FIG. 9(b) is a cross-sectional view taken along line X-X in FIG. 9(a).

The GaN-based LED element 50 comprises a GaN-based semiconductor film 52 formed on a substrate 51 via a buffer layer (not shown). The GaN-based semiconductor film 52 comprises an n-type layer 521 composed of an n-type conductive GaN-based semiconductor and a p-type layer 522 composed of a p-type conductive GaN-based semiconductor in this order from the substrate side. A metal n-side pad electrode 53 also serving as an ohmic electrode is formed on a surface of the n-type layer 521 exposed in a portion where the p-type layer 522 is partially removed. A TCO film 54 is formed as an electrode on the surface of the p-type layer 522.

In FIG. 9(a), a boundary between a flat section and a rough surface section 522a on the surface of the p-type layer 522 is indicated by a broken line H, and the surface of the p-type layer 522 is flat inside the broken line H. As shown in FIG. 9(a), the flat section of the surface of the p-type layer 522 comprises, in a region sandwiched between the n-side pad electrode 53 and the p-side pad electrode 54 (a region between two two-dot chain lines, hereinafter also referred to as “an inter-pad area”), a portion constricted along the direction of a line connecting the centers of these two pad electrodes to each other.

If the flat section of the surface of the p-type layer 522 is not provided with the above-mentioned constriction, the current flowing between the two pad electrodes shows a tendency of concentrating in the inter-pad area, which causes a fear that an emission pattern becomes unfavorable, or that deterioration rapidly proceeds in the inter-pad area. In the GaN-based LED element 50, therefore, the flat section of the surface of the p-type layer 522 is provided with the above-mentioned constriction in order that the area proportion of the rough surface section 522a in a portion of the surface of the p-type layer 522 where the layer is in contact with the TCO film 54 is greater inside the inter-pad area than outside the area, thereby suppressing the current concentration to the inter-pad area.

Preferred modes of the respective parts of the GaN-based LED elements according to the above-mentioned respective Embodiments will be described below.

As the substrate 11, 21, 31, 41 or 51, there can be preferably used a crystalline substrate (single-crystal substrate or template) made of a material such as sapphire, spinel, silicon carbide, silicon, GaN-based semiconductor (GaN, AlGaN or the like), gallium arsenide, gallium phosphide, gallium oxide, zinc oxide, LGO, NGO, LAO, zirconium boride and titanium boride. As a translucent substrate, there can be preferably used a substrate constituted of a material selected from sapphire, spinel, silicon carbide, GaN-based semiconductor, gallium phosphide, gallium oxide, zinc oxide, LGO, NGO, LAO and the like, depending on the emission wavelength of the light-emitting element. Further, as a conductive substrate, there can be preferably used a substrate made of silicon carbide, silicon, GaN-based semiconductor, gallium arsenide, gallium phosphide, gallium oxide, zinc oxide, zirconium boride, titanium boride or the like. When the conductive substrate is used, it is also possible to form an electrode for supplying the current to the n-type layer, on the substrate, instead of the surface of the n-type layer, thereby employing a vertical electrode type device structure.

In order that ELO (epitaxial lateral overgrowth) or facet growth, which is effective for reducing dislocation density in GaN-based semiconductor crystals, may occur, a mask layer can be formed on the surface of the substrate, or the surface of the substrate can be processed to form an uneven surface.

For the formation of the GaN-based semiconductor film 12, 22, 32, 42 or 52, there can be appropriately used a known method suitable for epitaxial growth of GaN-based semiconductor crystals, such as a MOVPE method (metal-organic vapor phase epitaxy method), a MBE method (molecular beam epitaxy method) and a HVPE method (hydride vapor phase epitaxy method). When a substrate not lattice-matched to GaN-based semiconductor crystals is used, it is desirable to allow a buffer layer to intervene between the substrate and the GaN-based semiconductor film. Referring to known techniques, a buffer layer such as a low-temperature buffer layer, a high-temperature buffer layer (single-crystal buffer layer) and a superlattice buffer layer, which comprises GaN-based semiconductor or another material, can be appropriately selected to use. When a vertical electrode type device structure is employed, the substrate and the n-type layer are required to be electrically connected to each other, so that the buffer layer may also be doped to be made conductive.

As another method for obtaining a structure in which a GaN-based semiconductor film is laminated on a substrate, there is also usable a method of forming the GaN-based semiconductor film on a growth substrate by an epitaxial growth method, thereafter removing the growth substrate from the GaN-based semiconductor film by using a method such as etching, grinding, abrasion and laser lift-off, and bonding a separately prepared substrate onto the GaN-based semiconductor film after the removal. Alternatively, there is also employable a method of depositing a metal layer on the surface of the GaN-based semiconductor film from which the growth substrate is removed, to a thickness of 50 μm or more by electrolytic plating or electroless plating, and using the metal layer as a substrate.

The n-type layer 121, 221, 321, 421 or 521 can be formed of GaN, AlGaN, InGaN or AlInGaN to which an n-type impurity such as Si and Ge is added. Preferably, it is formed to a thickness of 2 μm to 6 μm by using AlₐGa₁₋ₐN (0≦a≦0.05) to which Si is added to a concentration of 1×10¹⁸ cm⁻³ to 1×10¹⁹ cm⁻³.

The p-type layer 122, 222, 322, 422 or 522 can be formed of GaN, AlGaN, InGaN or AlInGaN to which a p-type impurity such as Mg and Zn is added. Preferably, it is formed to a thickness of 0.1 μm to 2.0 μm, and more preferably to a thickness of 0.1 μm to 0.5 μm, by using AlₐGa₁₋ₐN (0≦a≦0.2) to which Mg is added to a concentration of 2×10¹⁹ cm⁻³ to 1×10²⁰ cm⁻³. When the p-type impurity is hydrogen-passivated in a crystal growth process, hydrogen is dissociated by performing an annealing treatment or the like to activate the p-type impurity.

Each of the n-type layer and the p-type layer is not required to be homogeneous in a thickness direction, and in the inside of each layer, the impurity concentration, the crystal composition and the like may vary continuously or discontinuously in the thickness direction.

The pn junction part formed between the n-type layer and the p-type layer is desirably provided with an active layer so that a double hetero structure is formed. The active layer is, for example, a multiquantum well layer in which a plurality of In_{b1}Ga_{1-b1}N (0<b1≦0.5) well layers and a plurality of In_{b2}Ga_{1-b2}N (0≦b2<b1) barrier layers are alternately laminated.

In addition, various GaN-based semiconductor layers (including laminates) can be provided in the GaN-based semiconductor film, depending on the purpose, such as relaxation of stress strain, a reduction in dislocation density, improvement of electrostatic withstand voltage characteristics, improvement of light-emitting efficiency, a decrease in contact resistance and the like.

When the rough surface section is formed in the predetermined region of the p-type layer surface, a known roughening treatment method can be appropriately used.

Simple methods include a method of microprocessing a specific region of the p-type layer surface where the rough surface section is to be formed, by using techniques of photolithography and dry etching, to form an uneven surface comprising a number of convex portions (or concave portions) two-dimensionally dispersed.

In a preferred method, a protective mask with a predetermined opening pattern is formed on the p-type layer by using photolithography technique, and the p-type layer surface exposed in the opening is roughened by using any one of methods exemplified in the following (M1) to (M4), thereby being able to selectively form the rough surface section in the position of the opening.

(M1) A mask material layer with a pattern formed by phase separation of a block copolymer is made on the p-type layer surface, and the p-type layer surface is dry etched using the pattern as a mask (for example, patent document 3: JP-A-2003-218383 can be referred to).

(M2) A mask material layer with a pattern formed by an etching treatment using fine polystyrene particles as a mask is made on the p-type layer surface, and the p-type layer surface is dry etched using the pattern as a mask (for example, patent document 4: WO2004/061980 can be referred to).

(M3) The p-type layer surface is dry etched under conditions under which etching and deposition occur at the same time (for example, patent document 5: JP-A-2006-100518 can be referred to).

(M4) Fine particles made of inorganic material or metal are arranged on the p-type layer surface at a predetermined in-plane density, and the p-type layer surface is dry etched using these fine particles as a mask (for example, patent document 6: JP-A-2006-261659 can be referred to).

The processing method used for the roughening treatment of the p-type layer surface is not limited to dry etching. In an embodiment, after a protective mask with an opening is formed on the p-type layer, the p-type layer surface exposed in the opening can be roughened by using a blast method. According to this method, a “satin finished surface”-like non-directional uneven surface can be easily formed.

The p-type layer surface of the rough surface section is preferably an uneven surface which does not substantially comprise a flat planar portion, that is to say, an uneven surface where convex portions have a mountain-shaped (for example, triangular or semicircular) cross section and the bottom portions of concave portions have a V-shaped or U-shaped cross section.

The rms roughness of the p-type layer surface in the rough surface section within an area of 5×5 μm² is preferably 10 nm or more. When the distance from the bottom of the concave portion to the n-type layer is too small, there is a fear that a leak current path is formed. This distance is therefore preferably 100 nm or more, and more preferably 150 nm or more.

Particularly preferred examples of the uneven surface shapes include a shape in which convex portions showing a conical (circular conical, pyramidal) form, a frustum (circular truncated conical, truncated pyramidal) form, a columnar form, a dome form or the like are densely arranged. The arrangement of the convex portions may be either regular or irregular. In this shape, the average distance between the adjacent convex portions can be adjusted to 0.01 μm to 2 μm. When the convex portions are of a conical form, the distance between the convex portions means the distance between tips of the convex portions, and when the convex portions are of a frustum form, it means the distance between centers of upper surfaces (flat surfaces of leading ends of the convex portions). The average distance between the adjacent convex portions is particularly preferably approximately equivalent to the emission wavelength of the LED element, and specifically, from 0.2 to 2 times this wavelength. In the case of the GaN-based LED element emitting near-ultraviolet to green light, it is from 0.1 μm to 1.1 μm, although depending on the emission wavelength. The depth of the concave portions can be adjusted to 0.01 μm to 0.5 μm, and preferably, it is not less than a half of the average distance between the adjacent convex portions.

Other examples of the surface shapes of the rough surface sections include an uneven surface in which depressions of a conical, frustum or dome form are densely arranged. In the case of the GaN-based LED element emitting near-ultraviolet to green light, it is desirable that the average distance between the adjacent concave portions is adjusted to 0.1 μm to 1.1 μm, and that the depth of the concave portions is not less than a half of this distance.

In the GaN-based LED elements according to the above-mentioned Embodiments 1 to 4, the flat section and the rough surface section are mixed on the surface of the p-type layer covered with the TCO film, as shown in FIGS. 1 to 4 which are the cross-sectional views of the respective elements.

The flat section is a portion of the p-type layer surface, where the surface is not subjected to the roughening treatment. The surface of the p-type layer in the flat section is preferably an as-grown surface of the p-type layer, which has grown so as to show a mirror surface, but may be a mirror-like etched surface given by an etching method which scarcely generates nitrogen vacancies (for example, wet etching with acid). It is preferred that the p-type layer surface in the flat section has an rms roughness of less than 1 nm within an area of 5×5 μm² so that the junction state with the TCO film is uniform in the junction plane.

The flat section should not be such a small region as cannot be distinguished from the convex portions in the rough surface section. The purpose of providing the flat section is to secure a stable electrical connection between the p-type layer and the TCO film, so that the flat section should not be excessively segmentalized. For example, when the flat section contains a portion showing a slender strip form, the strip width thereof is desirably not less than 4 μm. Further, when the flat section contains a portion showing a dot form, the dot size is desirably large enough not to accommodate within a circle having a diameter of 4 μm.

Mixing modes of the flat section and the rough surface section include the cases where the flat section shows net-like, comb-like and branch-like patterns, a pattern in which a plurality of stripes are arranged parallel to one another and a pattern in which a plurality of dots are dispersed, as exemplified as the patterns of the first TCO film (equal to the patterns of the flat section) in the above-mentioned Embodiment 4. The pattern of the flat section and the pattern of the rough surface section are in a complementary relation with each other. Accordingly, when one of the flat section and the rough surface section shows a net-like pattern, the other shows a pattern in which a plurality of dots are dispersed.

Examples of the mixed patterns of the flat section and the rough surface section will be described more specifically.

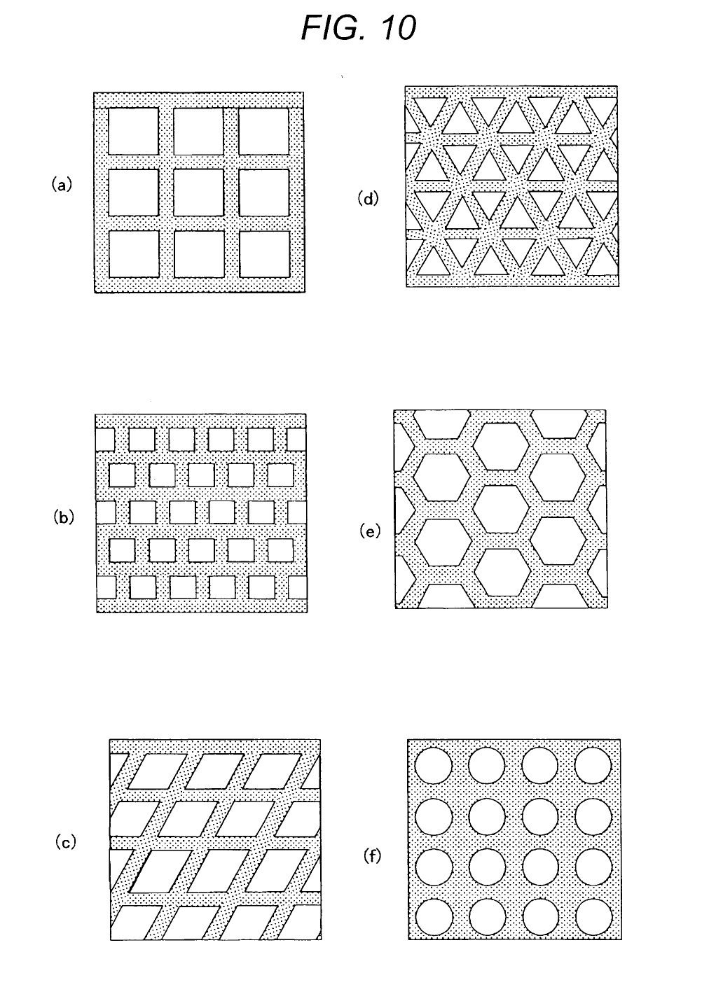

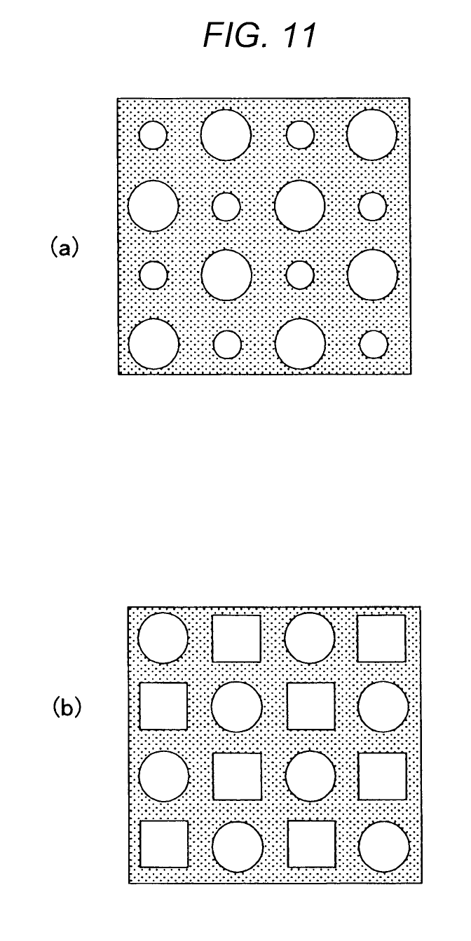

Various net-like patterns are exemplified in FIGS. 10(a) to 10(f) and FIGS. 11(a) and 11(b). In each drawing, a portion marked out with dots shows the net-like pattern.

There is no limitation on the shape of an opening in the net-like pattern, and it may be any of a rectangle shown in examples of FIGS. 10(a) and 10(b), a parallelogram shown in an example of FIG. 10(c), a triangle shown in an example of FIG. 10(d), a hexagon shown in an example of FIG. 10(e), a circle shown in an example of FIG. 10(f) and the like. It will be understood from the respective drawings that there is no limitation on the arrangement of the openings. Although not shown, the arrangement of the openings may be random.

The size of the openings in the net-like pattern may be non-uniform. FIG. 11(a) shows a net-like pattern comprising two kinds of circular openings different in size.

The shape of the openings in the net-like pattern may be non-uniform. FIG. 11(b) shows a net-like pattern comprising rectangular openings and circular openings.

It will be understood from the above explanation that the net-like pattern can comprises a plurality of openings different in size and shape.

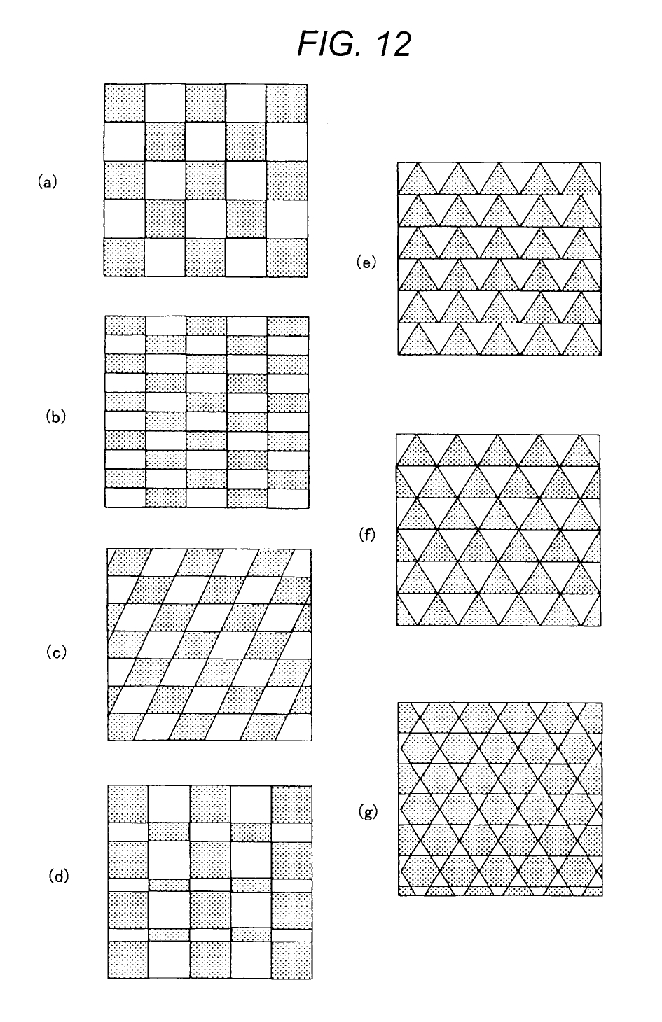

FIGS. 12(a) to 12(g) show a mixed pattern in which the flat sections and the rough surface sections form a checkered pattern (FIG. 12(a)) and modified mixed patterns thereof. In each pattern, portions marked out with dots may be either the flat sections or the rough surface sections. Naming generically the patterns of this kind, they can be said to be a pattern in which the flat sections are each in contact with the adjacent flat sections at points, and the rough surface sections are each in contact with the adjacent rough surface sections at points.

As described above, the flat sections and the rough surface sections can be allowed to be mixed on the surface of the p-type layer in various patterns. However, in terms of design convenience, preferred are the following mixed patterns:

(i) a mixed pattern in which the flat section(s) and the rough surface section(s) showing parallel stripes are alternately arranged;

(ii) a mixed pattern in which either the flat section or the rough surface section show a net-like pattern; and

(iii) a mixed pattern in which the flat sections are each in contact with the adjacent flat sections at points, and the rough surface sections are each in contact with the adjacent rough surface sections at points.

Particularly preferred is the mixed pattern of (iii). This is because when compared taking the area proportion of the flat sections and the rough surface sections arranged on the surface of the p-type layer as constant, border lines between both sections can be made longest in the mixed pattern of (iii), so that highest is a possibility that the light generated in the light emitting part under the flat section is emitted to the outside of the GaN-based semiconductor film through the rough surface section. For the same reason, a next preferred pattern is the pattern of (iii).

The mixed pattern formed by the flat sections and the rough surface sections on the surface of the p-type layer can comprise a periodic pattern. This periodic pattern may be either one having periodicity only in one direction or one having periodicity in two or more directions. The mixed pattern comprising a periodic pattern includes a mixed pattern in which different periodic patterns are combined in mosaic form, and the like, to say nothing of a mixed pattern in which the whole shows one periodic pattern. Preferably, the whole or the greater part of the mixed pattern is constituted by a periodic pattern. In a portion where the mixed pattern shows a periodic pattern, the flat sections and the rough surface sections can be uniformly mixed on the surface of the p-type layer by decreasing a repeating period of the pattern in at least one direction. This is effective for increasing in-plane uniformity of the amount of current supplied to the p-type layer. The repeating period of the pattern in the portion where the mixed pattern shows a periodic pattern is preferably from 5 μm to 60 μm, and more preferably from 10 μm to 40 μm, in at least one direction.

The area proportion of the flat sections in the mixed pattern can be, for example, from 20% to 90%. As the area proportion of the flat sections is decreased, the light extraction efficiency is improved, but, on the other hand, it becomes difficult to uniformly in-plane supply current to the light emitting part. Accordingly, the area proportion with which the ratio of output light power to input electric power becomes maximum is selected, taking into consideration a balance between the both effects.

A plurality of regions different in the mixed pattern formed by the flat sections and the rough surface sections, the area proportion of the flat sections in the pattern, and the like can be provided on the p-type layer. For example, the constitution of the GaN-based LED element according to the above-mentioned Embodiment 5 can be modified to constitute an element wherein the flat sections and the rough surface sections provided on the p-type layer surface are mixed in both the inside and outside of the inter-pad area, and the area proportion of the flat sections in the mixed pattern in the inter-pad area is lower than that in the outside area thereof.

In the n-side pad electrode 13, 23, 33, 43 or 53, a portion in contact with the n-type layer is preferably formed by using a simple substance such as Ti (titanium), Al (aluminum), W (tungsten) and V (vanadium), or an alloy containing one or more metals selected therefrom, when the electrode serves as an ohmic electrode to the n-type layer. The surface layer portion of the n-side pad electrode is preferably formed of Ag (silver), Au (gold), Sn (tin), In (indium), Bi (bismuth), Cu (copper), Zn (Zinc) or the like. The n-side pad electrode can also be formed on an ohmic electrode composed of TCO, which is formed on the n-type layer, instead of directly forming the n-side pad electrode on the n-type layer. The film thickness of the n-side pad electrode can be, for example, from 0.2 μm to 10 μm, and preferably from 0.5 μm to 2 μm.

When an ohmic electrode composed of TCO is formed on the n-type layer and a metal n-side pad electrode is formed on a part thereof, a region of the ohmic electrode (TCO film) not covered with the n-side pad electrode serves as a window region through which the light can be extracted. In an embodiment, flat sections and rough surface sections can be formed to make a predetermined mixed pattern on the surface of the n-type layer covered with this window region.

The TCO film 14, 24, 34, 44 or 54 can be formed by using various known TCOs such as indium oxide-based, zinc oxide-based, tin oxide-based and titanium oxide-based ones. Specifically, there are exemplified ITO (indium tin oxide), IZO (indium zinc oxide), AZO (aluminum zinc oxide), GZO (gallium zinc oxide), FTO (fluorine-doped tin oxide) and the like. The film thickness of the TCO film can be, for example, from 0.01 μm to 1 μm, preferably from 0.1 μm to 0.5 μm, and more preferably from 0.2 μm to 0.3 μm. The TCO film is preferably formed so as to have a transmission of 80% or more at the emission wavelength of the element. Further, the TCO film is preferably formed so as to have a resistivity of 5×10⁻⁴ Ωcm or less. As a method for forming the TCO film, there is exemplified a sputtering method, a reactive sputtering method, a vacuum vapor deposition method, an ion beam assisted evaporation method, an ion plating method, a laser ablation method, a CVD method, a spraying method, a spin coating method, a dipping method or the like. After film formation, the TCO film may be heat treated as needed.

Incidentally, it is also possible to modify the constitution of the GaN-based LED element according to each Embodiment described above to replace a part or the whole of the TCO film with a transparent conductive nitride film comprising TiN, ZrN, HfN or the like, or a composite type transparent conductive film in which a translucent metal thin film and a TCO film are laminated in various modes.

It has been already described that when the TCO film is a polycrystalline film, fine unevenness reflecting crystal grain boundaries is formed on the surface, so that the reflection on the TCO film surface becomes relatively weak. In a preferred embodiment, further, the surface smoothness of the TCO film is lowered by using a specific film forming method, thereby being able to increase the light emitted to the outside of the element through the TCO film used as a window. Specifically, the TCO film is formed by using a sputtering method in such a manner that a fine columnar structure containing many voids or holes, which corresponds to zone I of the Thornton model, is formed.

The Thornton model is one for describing the structure of a sputtered film, using as parameters the substrate temperature at the time of film formation, which is normalized by the melting point, and the film formation gas pressure, and it is known to be valid also for a thin film made of oxides including TCO. In order to obtain the film structure corresponding to zone I, what is necessary is just to form the film by adjusting the above-mentioned normalized substrate temperature to less than 0.3 and under conditions of relatively high Ar pressure. When the TCO film is formed by using a vacuum vapor deposition method, it is known that in an example of an ITO film, the surface shape can be controlled by selecting film forming conditions such as the vacuum atmosphere (particularly the oxygen partial pressure) during vapor deposition, the film forming rate, the film thickness and the content of Sn (patent document 8: JP-A-2008-235662).

By the way, in a region where the TCO film serves as the light extracting window, it is desirable to weaken confinement of light by decreasing the surface smoothness thereof. However, in a region where the pad electrode is formed, it is desired to increase the surface smoothness, conversely. This is because, the smoother is the surface of the TCO film, the smoother becomes the back surface of the pad electrode formed on the surface of the TCO film, resulting in the improvement of light reflectivity of the back surface. Further, an insulating transparent thin film can be partially inserted between the TCO film and the pad electrode. Also in that case, when the surface smoothness of the TCO film is increased, the light reflectivity at the interface between the TCO film and the transparent thin film is increased, and therefore the amount of light incident to the back surface of the pad electrode can be decreased.

Then, in a preferred embodiment, the TCO film is constituted so as to comprise a high smoothness film, having relatively high surface smoothness, and a low smoothness film, having relatively low surface smoothness. The pad electrode is formed on the surface of the high smoothness film, and at least a part of the low smoothness film is exposed in a region serving as a light extraction window. The low smoothness film can be a sputtered film with a structure corresponding to zone I in the above-mentioned Thornton model, and the high smoothness film can be a sputtered film with a structure corresponding to zone T or zone II in the above-mentioned Thornton model. More preferably, the high smoothness film is an amorphous IZO film. The surface of an amorphous IZO film is known to be extremely flat.

In a mode of such an electrode, the high smoothness film is first formed on the surface of the p-type layer, and then, the low smoothness film is formed on a surface of the high smoothness film. At this time, the high smoothness film is partially exposed instead of covering the whole surface thereof with the low smoothness film, and the pad electrode is formed on this partially exposed surface of the high smoothness film. The high smoothness film may be an amorphous IZO film or a film obtained by planarizing by polishing (CMP) the surface of a polycrystalline TCO film formed by a conventional vacuum vapor deposition method. A TCO film epitaxially grown on the p-type layer can also be used as the high smoothness film.

In another mode, a polycrystalline TCO film is first formed on the surface of the p-type layer by a conventional vacuum vapor deposition method, and then, the surface thereof is covered with a sputtered TCO film with a structure corresponding to zone I in the above-mentioned Thornton model. This sputtered film TCO is the low smoothness film. And an amorphous IZO film is formed as the high smoothness film on a part of this low smoothness film by a sputtering method, and an electrode is formed on this high smoothness film. Further, modifying this embodiment, after the polycrystalline TCO film is formed by the vacuum vapor deposition method, the sputtered TCO film corresponding to zone I may be formed as the low smoothness film on a part thereof, and the amorphous IZO film may be formed as the high smoothness film on another part thereof.

In addition, it is also possible to form both the low smoothness film and the high smoothness film by a vacuum vapor deposition method by controlling the surface shape of films through the selection of film forming conditions such as the vacuum atmosphere (particularly the oxygen partial pressure), the film forming rate, the film thickness and the content of Sn, as described in the above-mentioned patent document 8 (JP-A-2008-235662).

A material for the p-side pad electrode 15, 25, 35, 45 or 55 is not particularly limited, and for example, a portion in contact with the TCO film can be formed by using a platinum group (Rh, Pt, Pd, Ir, Ru or Os), Ni (nickel), Ti (titanium), W (tungsten), TiW, Ag (silver), Al (aluminum) or the like. The outer surface portion of the p-side pad electrode is preferably formed by Ag (silver), Au (gold), Sn (tin), In (indium), Bi (bismuth), Cu (copper), Zn (zinc) or the like. The film thickness of the p-side pad electrode can be, for example, from 0.2 μm to 10 μm, and preferably from 0.5 μm to 2 μm.

Excluding the surface of the pad electrode, which is used for connection with an external electrode, the surface of the element (particularly, the surface of a portion made of a conductive material) may be covered with an insulating protective film. The insulating protective film can be formed by a metal oxide, metal nitride or metal oxynitride having high transmission at the emission wavelength of the LED element. Specifically, there can be exemplified silicon oxide, silicon nitride, silicon oxynitride, aluminum oxide, aluminum nitride, tantalum oxide, zirconium oxide, hafnium oxide and the like.

There is no limitation on the mounting form of the GaN-based LED element 10, 20, 30, 40 or 50, and it may be mounted either face-up or face-down. After face-down mounting, the substrate can be removed from the LED element by using technologies disclosed in patent document 7 (JP-T-2007-517404 (the term “JP-T” as used herein means a published Japanese translation of a PCT patent application); WO2005/062905).

The invention is not limited to the embodiments described expressly in this specification, and various variations are possible without departing from the spirit of the present invention.

The invention has been described in detail with reference to the specific embodiments, but it will be obvious to those skilled in the art that various changes and modifications can be made without departing from the spirit and scope of the invention.

This application is based on Japanese Patent Application No. 2007-339721 filed on Dec. 28, 2007, the contents of which are incorporated herein by reference.

### INDUSTRIAL APPLICABILITY

The invention can provide a GaN-based LED element which can be suitably used for applications requiring high output power, including illumination applications, and more specifically, a GaN-based LED element using a TCO film as an electrode can be further improved to increase output power.

1-16. (canceled)

17. A GaN-based LED element, comprising:
a semiconductor laminated structure comprising a p-type GaN-based semiconductor layer having an upper surface and a lower surface, an n-type GaN-based semiconductor layer arranged on the lower surface of the p-type GaN-based semiconductor layer, and a light emitting part comprising a GaN-based semiconductor interposed between the n-type GaN-based semiconductor layer and the p-type GaN-based semiconductor layer;
a p-side electrode formed on the upper surface of the p-type GaN-based semiconductor layer; and
an n-side electrode electrically connected to the n-type GaN-based semiconductor layer,
wherein the p-side electrode comprises a TCO film and a metal electrode formed on a part of the TCO film,
wherein the upper surface of the p-type GaN-based semiconductor layer is at least partially covered by the TCO film,
wherein the upper surface of the p-type GaN-based semiconductor layer which is covered with the TCO film has a rough portion and a mirror portion, the mirror portion comprising a first mirror portion,
wherein the metal electrode is arranged above the first mirror portion, and
wherein the rough portion is arranged only in regions other than a region directly under the metal electrode.

18. The LED element of claim 17, wherein a surface of the rough portion comprises an uneven surface in which depressions of a conical, frustum, or dome form are densely arranged.

19. The LED element of claim 17, wherein a surface of the rough portion comprises an uneven surface with convex portions having a mountain-shaped cross section and bottom portions of concave portions having a V-shaped or U-shaped cross section, and has substantially no flat planar portion.

20. The LED element of claim 17, wherein the TCO film is a polycrystalline film.

21. The LED element of claim 17, wherein an insulating film is interposed between the TCO film and the p-type semiconductor layer, and the insulating film blocks a current supply from the TCO film to the p-type GaN-based semiconductor layer directly under the metal electrode, and the insulating film is a transparent thin film made of an inorganic material.

22. The LED element of claim 17, wherein the mirror portion comprises a second mirror portion, and the second mirror portion and the rough portion are arranged to form a mixed pattern in regions other than the region directly under the metal electrode on the upper surface of the GaN-based semiconductor covered with the TCO film.

23. The LED element of claim 22, wherein the second mirror portion shows a net pattern in the mixed pattern.

24. The LED element of claim 22, wherein the second mirror portion shows a comb pattern in the mixed pattern.

25. The LED element of claim 22, wherein the second mirror portion shows a branched pattern in the mixed pattern.

26. The LED element of claim 17, wherein the TCO film comprises indium tin oxide (ITO), indium zinc oxide (IZO), aluminum zinc oxide (AZO), gallium zinc oxide (GZO), or fluorine-doped tin oxide (FTO).
